(19) United States
(12) Patent Application Publication
(10) Pub. No.: US 2025/0393156 A1
(43) Pub. Date: Dec. 25, 2025

(54) DRIVE CADDY AND LOCKING CHANNELS

(71) Applicant: Zoho Corporation Private Limited, Kanchipuram District (IN)

(72) Inventors: Yash Manoj Kadu, Nagpur (IN); Rushikesh Vijayrao Pawade, Nagpur (IN); Mangesh Devidas Sadafale, Nagpur (IN); Animesh Anil Admane, Nagpur (IN)

(73) Assignee: Zoho Corporation Private Limited, Kanchipuram District, TN (IN)

(21) Appl. No.: 19/012,111

(22) Filed: Jan. 7, 2025

Related U.S. Application Data
(60) Provisional application No. 63/679,227, filed on Aug. 5, 2024.

(30) Foreign Application Priority Data
Jun. 21, 2024 (IN) 202441047940

(51) Int. Cl. H05K 7/14

(52) U.S. Cl. CPC H05K 7/1489

(57) ABSTRACT

A caddy for housing a storage drive includes a caddy body with a front section having a handle slot and mounting brackets for connecting to the storage drive. The brackets feature wide and narrow sections. A unitary handle, pivotally attached to the front section, operates between open and closed positions. The unitary handle comprises ends with a finger rest, a handle pin for securing, and a resilient latch, alongside a grip and a body with air-admitting openings. When closed, the handle body resides within the handle slot. The caddy interfaces with guide plates with channel partitions forming channels, each with a latch pocket and wide portions separated by a constriction that prevents caddy over-insertion or misorientation.

### BACKGROUND

Drive caddies, also known as drive trays or drive carriers, are essential components in server environments. They are used to house and secure hard-disk drives (HDDs) or solid-state drives (SSDs), collectively “storage drives” or just “drives,” in a server chassis. Many servers support hot-swappable storage drives, allowing drives to be replaced or added without powering down the server.

Drive caddies are available for different form factors, typically 2.5-inch and 3.5-inch drives, matching the common sizes of HDDs and SSDs. By using appropriate drive caddies, server administrators can efficiently manage storage devices, ensuring reliability, case of maintenance, and scalability in their server environments.

### BRIEF DESCRIPTION OF THE DRAWINGS

The subject matter presented herein is illustrated by way of example and not by way of limitation in the figures of the accompanying drawings, in which like reference numerals refer to similar elements and in which:

FIG. 1 depicts a drive caddy 100 that receives and supports a storage drive 105.

FIG. 2 depicts an enclosure 200 with four fully inserted and one partially inserted caddy 100 of the type depicted in FIG. 1.

FIG. 3 depicts caddy 100 next to one of guide plates 205 to illustrate how bracket 117 mates with one of channels 215 in guide plate 205.

FIG. 4 depicts an enclosure 400 with eight caddies 100 disposed between a pair of guide plates encompassed within a conductive housing 405.

### DETAILED DESCRIPTION

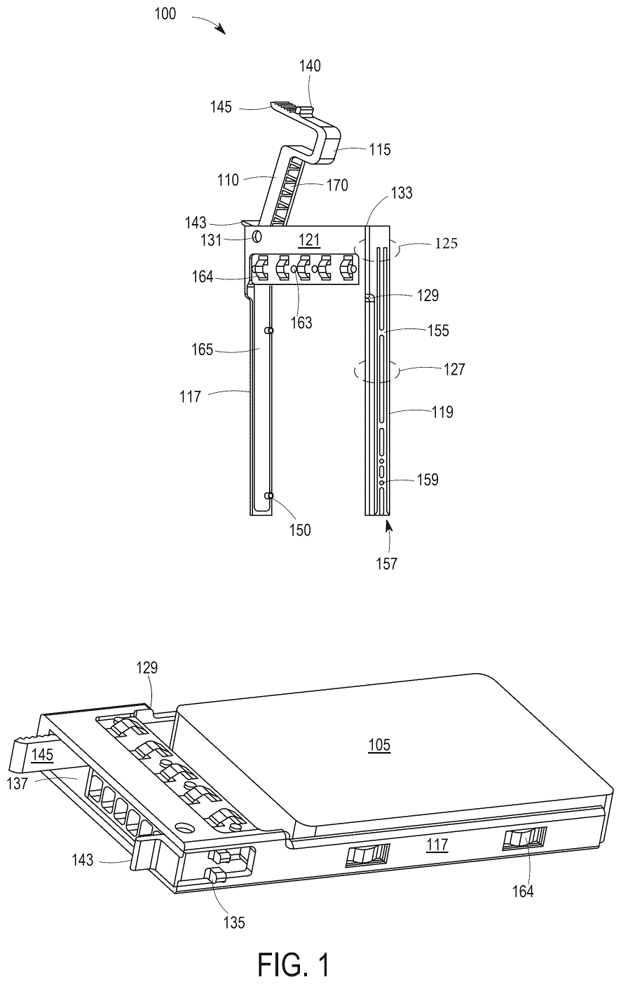

FIG. 1 depicts a drive caddy 100 that receives and supports a storage drive 105. One or more caddies 100 can be installed in a computer system, such as a server. A unitary handle 110 has a flexible U-shaped structure 115 that serves as a spring, eliminating the need for additional springs in these locking mechanisms. Mounting brackets 117 and 119 extend from a front section 121 of caddy 100 and include wide sections 125 and narrow sections 127 that form caddy stops 129 between them. As detailed below, caddy stops 129 ensure caddy 100 is oriented correctly and prevent over-insertion.

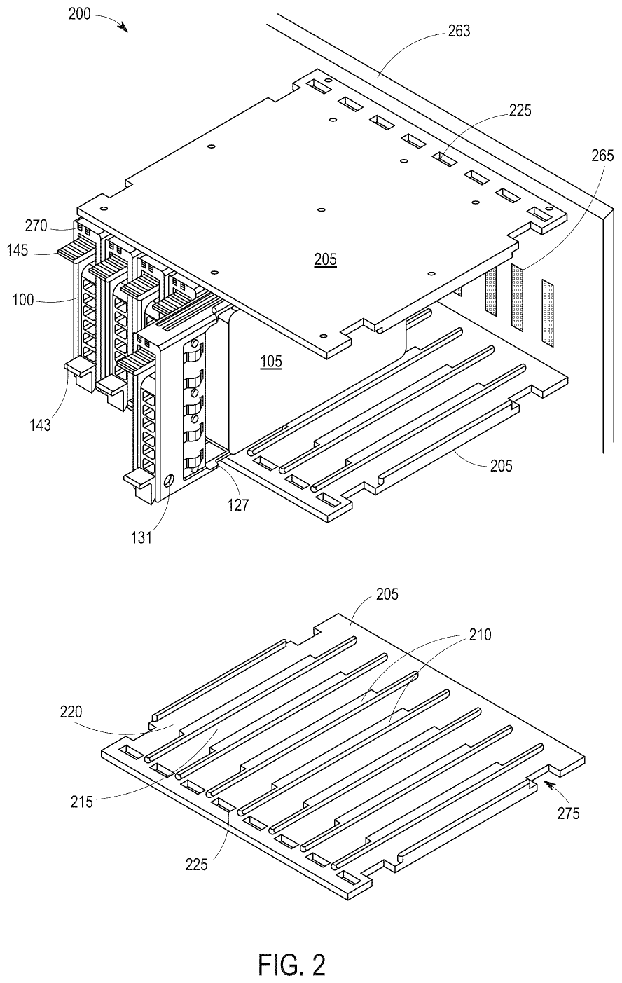

Handle 110 pivots at a pivot point defined by holes 131 in body 133 of caddy 100. Pivoting handle 110 from an open position to a closed position inserts handle 110 neatly in a handle slot 137 in the face of body 133. Handle 110 is a lever with a fulcrum at pivot point 131 and a load arm 135 that extends from body 133 when handle 110 is in a closed position to lock caddy 100 in place (FIG. 2). In this closed position, a finger rest 143 opposite a grip 145 on handle 110 allows a user to disengage latch 140 to pivot handle 110 away from caddy body 133. In doing so, load arm 135 urges caddy 100 out of a corresponding channel (FIG. 2) to case caddy removal. Opposing pairs of mounting pins 150 in brackets 117 and 119 engage with holes (not shown) in storage drive 105 in lieu of screws, simplifying installation and removal.

A recess 155 on bracket 119 receives an optical element (FIG. 2) of e.g. acrylic to guide light from optical inputs 157 to the face of caddy body 133. The light path or paths transmit light from e.g. LEDs on a printed-circuit board (PCB) adjacent caddy 100 to light ports (FIG. 2) on the visible end of an installed caddy 100. A locking pattern 159 in recess 155 locks the optical element in place without fasteners or adhesives. The PCB is communicatively connected to computer components (not shown) that require access to memory within drive 105. Caddy body 133 includes a recessed portion with cage locks 160 to attach electromagnetic-interference (EMI) finger stock 163 with EMI fingers 164 in an EMI cage 165. One or more vents 170 in handle 110 allow air to flow through handle 110 and front section 121 of caddy body 133 when handle 110 is in the closed position.

Handle 110 is of unitary construction, which is to say it is made of a single piece of material. Handle 110 can be made inexpensively by e.g. injection molding and incorporates flexible U-shaped structure 115 to flex for locking and unlocking. Handle 110 can be made of inexpensive and lightweight plastic. Recycled plastic minimizes environmental impact and can be more cost-effective than standard materials.

FIG. 2 depicts an enclosure 200 with four fully inserted and one partially inserted caddy 100 of the type depicted in FIG. 1. Enclosure 200 includes a pair of identical guide plates 205, each with partitions 210 that form channels 215 for receiving and supporting respective brackets 117/119. Each channel 215 has a constriction 220 that admits the narrow section 125 of one of the brackets but excludes the wide section 125 to prevent caddy over insertion. Partitions 210 are sized to allow air flow between caddies 100 for thermal management. Channels 215 are asymmetrical so each caddy 100 can only be fully inserted in the correct orientation.

Channels 215 include a latch pockets 225 to receive the ends of load arms 135 of handles 110. Each handle 110 is a lever with a fulcrum at pivot point 131 defining an effort arm that is long relative to load arm 135. Opening handle 110 moves load arm 135 out of the way to facilitate caddy insertion. Finger rest 143 impinges one of guide plates 205 such that drive 115 nearly mates with a corresponding connector 265. Closing handle 110 from this position causes the end of load arm 135 to engage a latch pocket 225, urging drive 115 onto connector 265 as handle 110 enters handle slot 137. When handle 110 is fully closed, latch 140 snaps handle 110 in place. Load arm 135 extends into latch pocket 225, locking caddy 100 between guide plates 205 in a pair of opposing channels 215.

The lever action of handle 110 works in reverse to facilitate caddy removal. The user applies a compressive force between grip 143 and finger rest 145 to unlatch handle 100. Pulling the relatively long effort arm of handle 110 away from caddy body 133 causes load arm 135 to apply a force against latch pocket 225 that assists in decoupling drive 105 from connector 265.

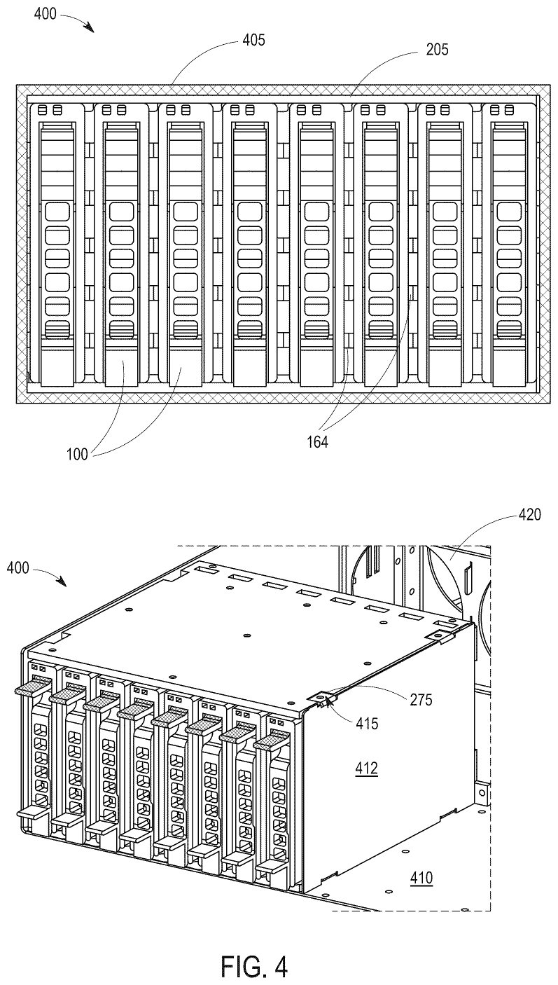

Guide plates 205 are identical for case of manufacture but are installed in opposite orientations so partitions 210 have mirror symmetry. Latch pockets 255 at the rear of enclosure 200 are not used. A printed-circuit board (PCB) 263 behind guild plates 205 includes connectors 265 that mate with connectors on drives 105 (not shown) and LEDs that shine into optical inputs 157 to made visible via light ports 270 on the faces of caddies 100. Slots 275 on guide plates 205 make way for tabs introduced later in connection with FIG. 4.

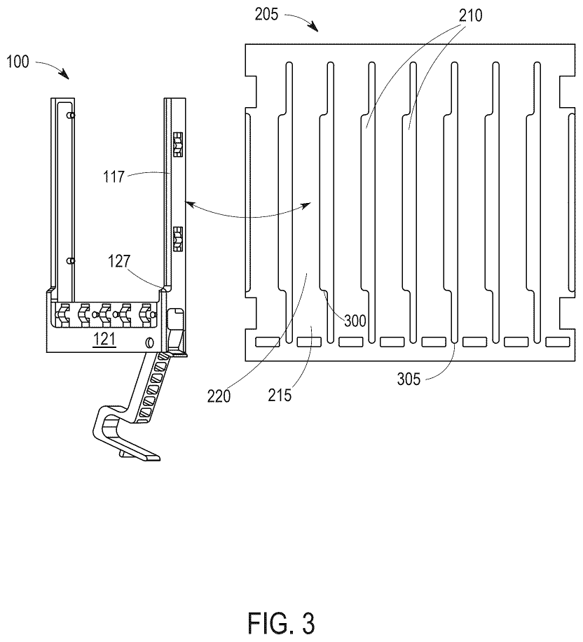

FIG. 3 depicts caddy 100 next to one of guide plates 205 to illustrate how bracket 117 mates with one of channels 215 in guide plate 205. Stop 127 formed between the wide and narrow regions of bracket 117 contacts a similar stop 300 that marks the beginning of a channel constriction 220 too narrow to admit the wide portion of bracket 117. If caddy 100 is misoriented, the positions of grip 145 and rest 143 reversed relative to caddies 100 of FIG. 2, stop 127 contacts a partition end 305 rather than shoulder 300 that marks the beginning of a constriction 220. The length of the wide portion of each channel 215 is such that a drive installed upside down could not contact the corresponding PCB connector. When caddy 100 is properly oriented, load arm 135 extends into a corresponding latch pocket 225 when closing handle 110, an action that urges caddy 100 against PCB 263 so drive 105 mates with connector 265.

FIG. 4 depicts an enclosure 400 with eight caddies 100 disposed between a pair of guide plates 205 encompassed within a conductive housing 405. EMI fingers 164 electrically interconnect adjacent caddies 100 and conductive housing 405 for EMI shielding. Dummy caddies (not shown) can be installed in place of missing caddies 100 to provide EMI shielding for enclosures that lack one or more storage drives.

Conductive housing 405 can include a chassis or front tray 410 with vertical side support, e.g. module partition(s) 412 with tabs 415 that fit in guide-plate slots 275. Tabs 415 can have holes for fasteners to chassis 410. A fan housing 420 draws air through and between caddies 100. This air can be directed downstream to cool e.g. processors and other server components (not shown).

Variations of these embodiments, including embodiments in which features are used separately or in any combination, will be obvious to those of ordinary skill in the art. Therefore, the spirit and scope of the appended claims should not be limited to the foregoing description. In U.S. applications, only those claims specifically reciting “means for” or “step for” should be construed in the manner required under 35 U.S.C. section 112(f).

What is claimed is:

1. A caddy for housing a storage drive, the caddy comprising:
a caddy body to support the storage drive, the caddy body including:
a front section with a handle slot; and
first and second mounting brackets extending from the front section to connect to the storage drive, each of the first and second mounting brackets including a wide section and a narrow section; and
a unitary handle pivotally connected to the caddy body and having an open, unlocked position and a closed, locked position, the unitary handle including:
a first handle end pivotally connected to the front section of the caddy body, the first handle end having:
a finger rest that extends from the front section when the unitary handle is in the closed position; and
a handle pin that extends from the front section of the caddy body when the unitary handle is in the closed position;
a second handle end having:
a resilient handle latch;
a handle grip that extends from the front section when the unitary handle is in the closed position; and
a handle body extending between the first handle end and the second handle end and within the unitary handle slot when the unitary handle is in the closed position, the handle body including at least one opening to admit air through the handle body and the caddy body when the unitary handle is in the closed position.

2. The caddy of claim 1, resilient handle latch including a U-shaped bend that flexes when the handle grip is urged towards the finger rest.

3. The caddy of claim 1, wherein the unitary handle consists essentially of plastic.

4. The caddy of claim 1, each of the first and second mounting brackets further comprising a step transition between the wide section and the narrow section.

5. The caddy of claim 1, wherein at least one of the first and second mounting brackets includes a recess with an optical element extending along the one of the first and second mounting brackets, the recess including a locking pattern for affixing the optical element within the recess.

6. The caddy of claim 1, wherein the front section includes a single opening to admit the air from the handle body.

7. The caddy of claim 1, wherein the first handle pivot point comprises a hole in the front section of the caddy body.

8. An enclosure encompassing a plurality of the caddy of claim 1.

9. The enclosure of claim 8, further comprising a first guide plate having first guide-plate channels engaging the first mounting brackets of the caddies and a second guide plate having second guide-plate channels engaging the second mounting brackets of the caddies.

10. The enclosure of claim 9, wherein the first guide plate is identical to the second guide plate.

11. The enclosure of claim 9, wherein the first guide-plate channels include wide-slot sections to engage the wide sections of the first mounting brackets and narrow-slot sections to engage the narrow sections of the first mounting brackets.

12. The enclosure of claim 11, wherein the first guide-plate channels include second-wide-slot sections to engage the narrow section of the first mounting brackets.

13. The enclosure of claim 9, wherein the first and second guide plates are non-conductive.

14. The enclosure of claim 9, wherein the first guide plate includes first latch pockets to mate with the unitary handles and the second guide plate includes second latch pockets on an end of the second guide plate opposite the unitary handles.

15. A guide plate for a storage-drive caddy, the guide plate comprising:
channel partitions defining channels between them, each channel including a latch pocket at one channel end and first and second wide channel portions separated by a channel constriction.

16. The guide plate of claim 15, wherein the channel constriction is longer than either of the first and second wide channel portions.

17. The guide plate of claim 16, wherein the channel constriction is longer than the first and second wide channel portions combined.

18. The guide plate of claim 15, each channel partition including first and second caddy stops between the channel constriction and the first and second wide channel portions.
